(19) United States
(12) Patent Application Publication
(10) Pub. No.: US 2017/0186822 A1
(43) Pub. Date: Jun. 29, 2017

(54) LIGHT EMITTING DIODE, DISPLAY SUBSTRATE AND DISPLAY APPARATUS HAVING THE SAME, AND FABRICATING METHOD THEREOF

(71) Applicants: BOE TECHNOLOGY GROUP CO., LTD., Beijing (CN); Ordos Yuansheng Optoelectronics Co., Ltd., Ordos (CN)

(72) Inventors: Weilin Lai, Beijing (CN); Juanjuan Bai, Beijing (CN); Renrong Gai, Beijing (CN); Minghua Xuan, Beijing (CN)

(73) Assignees: BOE TECHNOLOGY GROUP CO., LTD., Beijing (CN); Ordos Yuansheng Optoelectronics Co., Ltd., Ordos (CN)

(21) Appl. No.: 15/303,007

(22) PCT Filed: Feb. 22, 2016
(86) PCT No.: PCT/CN2016/074269

§ 371 Date: Oct. 9, 2016

(30) Foreign Application Priority Data
Jul. 17, 2015 (CN) 201510424335.0

(51) Int. Cl. H01L 27/32; H01L 51/00; H01L 51/50; H01L 51/56

(52) U.S. Cl. CPC H01L 27/3211; H01L 27/3213; H01L 51/56; H01L 51/0011; H01L 51/504; H01L 51/5012; H01L 2251/5315; H01L 2251/5323; H01L 27/3244; H01L 27/3281

(57) ABSTRACT

The present application discloses a light emitting diode, comprising a pixel unit comprising at least a first sub-pixel in a first region, a second sub-pixel in a second region and a third sub-pixel in a third region; a first electrode layer comprising a first sub-electrode for driving the first sub-pixel, a second sub-electrode for driving the second sub-pixel, and a third sub-electrode for driving the third sub-pixel; a second electrode layer opposite to the first electrode layer; and a light emitting unit between the first electrode layer and the second electrode layer. The light emitting unit comprises a first light emitting layer in the first sub-pixel for emitting light of a first color; a second light emitting layer in the second sub-pixel for emitting light of a second color; and a third light emitting layer in the third sub-pixel for emitting light of a third color. The second light emitting layer is in a same layer as the first light emitting layer. The third light emitting layer is in a layer different from the first light emitting layer and the second light emitting layer. The third light emitting layer has at least a continuous emissive layer extending throughout the third region. The first color, the second color, and the third color are three different colors.

### CROSS-REFERENCE TO RELATED APPLICATION

This application claims priority to Chinese Patent Application No. 201510424335.0, filed on Jul. 17, 2015, the contents of which are incorporated by reference in the entirety.

### TECHNICAL FIELD

The present invention relates to display technology, more particularly, to a light emitting diode, a display substrate and a display apparatus having the same, and a fabricating method thereof.

### BACKGROUND

As compared to other display apparatuses such as liquid crystal display (LCD) apparatuses, the organic light emitting diode (OLED) display apparatuses are self-emitting apparatuses that do not require a backlight. Having the advantages of fast response, a wider viewing angle, high brightness, more vivid color rendering, thinner and lighter, they have found a wide range of applications in display field.

### SUMMARY

In one aspect, the present disclosure provides a light emitting diode, comprising a pixel unit comprising at least a first sub-pixel in a first region, a second sub-pixel in a second region and a third sub-pixel in a third region; a first electrode layer comprising a first sub-electrode for driving the first sub-pixel, a second sub-electrode for driving the second sub-pixel, and a third sub-electrode for driving the third sub-pixel; a second electrode layer opposite to the first electrode layer; and a light emitting unit between the first electrode layer and the second electrode layer. The light emitting unit comprises a first light emitting layer in the first sub-pixel for emitting light of a first color; a second light emitting layer in the second sub-pixel for emitting light of a second color; and a third light emitting layer in the third sub-pixel for emitting light of a third color. The second light emitting layer is in a same layer as the first light emitting layer. The third light emitting layer is in a layer different from the first light emitting layer and the second light emitting layer. The third light emitting layer has at least a continuous emissive layer extending throughout the third region. The first color, the second color, and the third color are three different colors.

Optionally, the third light emitting layer is a continuous emissive layer extending throughout the first region, the second region, and the third region.

Optionally, the pixel unit further comprises a fourth sub-pixel in a fourth region; the first electrode layer further comprises a fourth sub-electrode for driving the fourth sub-pixel; the light emitting unit further comprises a fourth light emitting layer in the fourth sub-pixel for emitting light of a fourth color; the fourth light emitting layer is in a same layer as the first light emitting layer and the second light emitting layer.

Optionally, the fourth color is different from the first color, the second color, and the third color.

Optionally, the third light emitting layer covers a region substantially equal o an entire area of the light emitting unit.

Optionally, the third light emitting layer has a single-layer structure.

Optionally, the third light emitting layer comprises two or more sub-layers.

Optionally, the third light emitting layer is on a side of the first electrode layer distal to a base substrate; the first light emitting layer and the second light emitting layer are on a side of the third light emitting layer distal to the first electrode layer, and the second electrode layer is on a side of the first light emitting layer and the second light emitting layer distal to the third light emitting layer.

Optionally, the first light emitting layer and the second light emitting layer are on a side of the first electrode layer distal to a base substrate; the third light emitting layer is on a side of the first light emitting layer and the second light emitting layer distal to the first electrode layer, and the second electrode layer is on a side of the third light emitting layer distal to the first light emitting layer and the second light emitting layer.

Optionally, the first color, the second color and the third color are three different colors selected from red, green and blue.

Optionally, the light emitting diode further comprises a hole transport layer between the light emitting unit and the first electrode layer, and an electron transport layer between the light emitting unit and the second electrode layer.

Optionally, the first electrode layer is an anode layer, and the second electrode layer is a cathode layer.

In another aspect, the present disclosure provides a method of fabricating a display substrate comprising a plurality of pixel units, each of which comprising at least a first sub-pixel in a first region, a second sub-pixel in a second region and a third sub-pixel in a third region; the method comprising forming a first electrode layer; the first electrode layer comprises a first sub-electrode for driving the first sub-pixel, a second sub-electrode for driving the second sub-pixel, and a third sub-electrode for driving the third sub-pixel; forming a second electrode layer opposite to the first electrode layer; and forming a light emitting region between the first electrode layer and the second electrode layer comprising a plurality of light emitting units.

Optionally, the step of forming each of the plurality of light emitting units comprises forming a first light emitting layer in the first sub-pixel for emitting light of a first color; forming a second light emitting layer in the second sub-pixel for emitting light of a second color; and forming a third light emitting layer in the third sub-pixel for emitting light of a third color. The second light emitting layer is formed in a same layer as the first light emitting layer. The third light emitting layer is formed in a layer different from the first light emitting layer and the second light emitting layer. The third light emitting layer has at least a continuous emissive layer extending throughout the third region. The first color, the second color, and the third color are three different colors.

Optionally, the third light emitting layer is a continuous emissive layer extending throughout the first region, the second region, and the third region.

Optionally, each pixel unit further comprises a fourth sub-pixel in a fourth region; the first electrode layer further comprises a fourth sub-electrode for driving the fourth sub-pixel, the step of forming each of the plurality of light emitting units further comprises forming a fourth light emitting layer in the fourth sub-pixel for emitting light of a fourth color; the fourth light emitting layer is in a same layer as the first light emitting layer and the second light emitting layer; and the fourth color is different from the first color, the second color, and the third color.

Optionally, the first light emitting layer is formed by vapor deposition using a first mask plate; the second light emitting layer is formed by vapor deposition using a second mask plate; and the third light emitting layer is formed by vapor deposition using a third mask plate; the third mask plate having an opening larger than a sum of those of the first mask plate and the second mask plate.

Optionally, the third mask plate has an opening substantially corresponding to an entire area of a light emitting unit.

Optionally, the first mask plate and the second mask plate is a single mask plate.

Optionally, the third light emitting layer has a single-layer structure.

Optionally, the third light emitting layer comprises two or more sub-layers.

Optionally, the third light emitting layer is formed on a side of the first electrode layer distal to a base substrate; the first light emitting layer and the second light emitting layer are formed on a side of the third light emitting layer distal to the first electrode layer, and the second electrode layer is formed on a side of the first light emitting layer and the second light emitting layer distal to the third light emitting layer.

Optionally, the first light emitting layer and the second light emitting layer are formed on a side of the first electrode layer distal to a base substrate; the third light emitting layer is formed on a side of the first light emitting layer and the second light emitting layer distal to the first electrode layer, and the second electrode layer is formed on a side of the third light emitting layer distal to the first light emitting layer and the second light emitting layer.

Optionally, the first color, the second color and the third color are three different colors selected from red, green and blue.

Optionally, the method further comprises forming a hole transport layer between the light emitting region and the first electrode layer, and forming an electron transport layer between the light emitting region and the second electrode layer.

Optionally, the first electrode layer is an anode layer, and the second electrode layer is a cathode layer.

In another aspect, the present disclosure provides a display substrate comprising a plurality of the light emitting diode described herein or manufactured by a method described herein.

In another aspect, the present disclosure provides a display apparatus comprising the display substrate described herein.

### BRIEF DESCRIPTION OF THE FIGURES

The following drawings are merely examples for illustrative purposes according to various disclosed embodiments and are not intended to limit the scope of the present invention.

FIG. 1 is a diagram illustrating the structure of a conventional light emitting diode.

FIG. 2A is a diagram illustrating a top-emission type light emitting diode in some embodiments.

FIG. 2B is a diagram illustrating a bottom-emission type light emitting diode in some embodiments.

FIG. 2C is a diagram illustrating a dual-emission type light emitting diode in some embodiments.

FIG. 3A is a diagram illustrating a top-emission type light emitting diode in some embodiments.

FIG. 3B is a diagram illustrating a bottom-emission type light emitting diode in some embodiments.

FIG. 3C is a diagram illustrating a dual-emission type light emitting diode in sonic embodiments.

FIG. 4A is a diagram illustrating a top-emission type light emitting diode in some embodiments.

FIG. 4B is a diagram illustrating a bottom-emission type light emitting diode in some embodiments.

FIG. 4C is a diagram illustrating a dual-emission type light emitting diode in some embodiments.

FIG. 5 is a flow chart illustrating a method of fabricating a display substrate in some embodiments.

### DETAILED DESCRIPTION

The disclosure will now describe more specifically with reference to the following embodiments. It is to be noted that the following descriptions of some embodiments are presented herein for purpose of illustration and description only. It is not intended to be exhaustive or to be limited to the precise form disclosed.

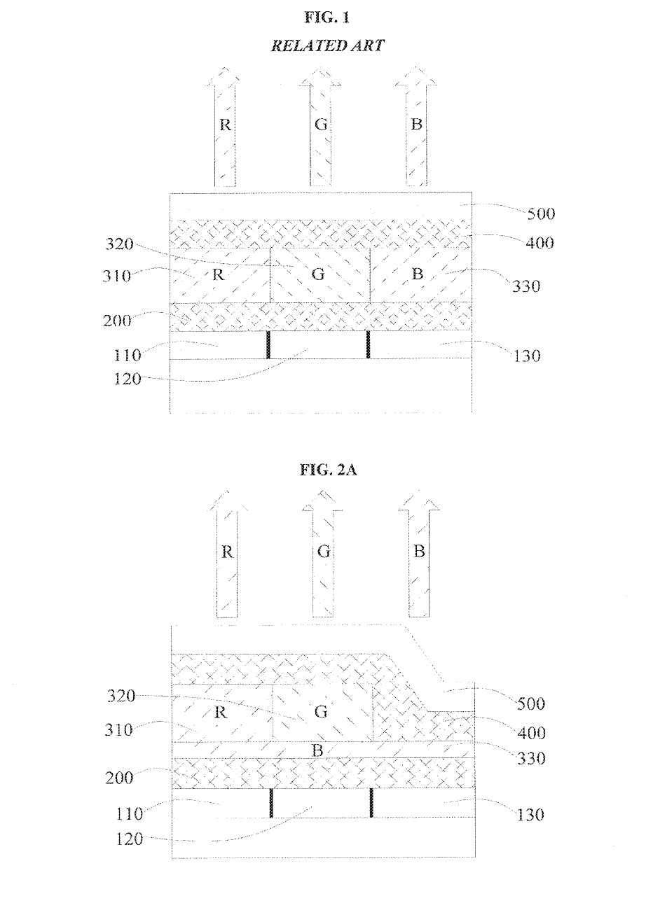

Typically, a conventional organic light emitting display apparatus includes an array substrate having a plurality of pixel units, each of which contains a light emitting diode. FIG. 1 is a diagram illustrating the structure of a conventional light emitting diode. Referring to FIG. 1, the conventional light emitting diode includes an anode layer, a hole transport layer 200, a light emitting layer, an electron transport layer 400, and a cathode layer 500. The light emitting layer in FIG. 1 includes a red light emitting layer 310, a green light emitting layer 320, and a blue light emitting layer 330. The anode layer includes a first anode layer 110 corresponding to the red light emitting layer 310, a second anode layer corresponding to the green light emitting layer 320, and a third anode layer 130 corresponding to the blue light emitting layer 330.

In a method of manufacturing an array substrate having a conventional light emitting diode, the light emitting diode is typically formed by vapor deposition utilizing a mask plate. For making a conventional light emitting diode having three light emitting layers of three different colors, vapor deposition processes using three different mask plates each having an opening corresponding to a different position on the light emitting diode are required. Each tight emitting layer has to be accurately deposited on the substrate. This demands a high alignment accuracy, making the manufacturing process more complicated.

The present disclosure provides a superior light emitting diode, a display substrate and a display apparatus having the same, and a fabricating method thereof that overcome the shortcomings of the convention light emitting diode, display substrate, and manufacturing method. In some embodiments, the present disclosure provides a light emitting diode having a pixel unit comprising at least a first sub-pixel in a first region, a second sub-pixel in a second region and a third sub-pixel in a third region. The light emitting diode includes a first electrode layer; a second electrode layer opposite to the first electrode layer; and a light emitting unit between the first electrode layer and the second electrode layer. The present light emitting unit includes a first light emitting layer of a first light emitting material corresponding to a first sub-pixel for emitting light of a first color; a second light emitting layer of a second light emitting material corresponding to a second sub-pixel for emitting light of a second color; and a third light emitting layer of a third light emitting material corresponding to a third sub-pixel for emitting light of a third color. The first light emitting layer and the second light emitting layer are in a same layer. The third light emitting layer is in a layer different from the first light emitting layer and the second light emitting layer. Optionally, the third light emitting layer has at least a continuous emissive layer extending throughout the third region. Optionally, the third light emitting layer is a continuous emissive layer extending throughout a first region corresponding to the first sub-pixel, a second region corresponding to the second sub-pixel, and a third region corresponding to the third sub-pixel. For example, the third light emitting layer covers a region corresponding to an entire area of the light emitting unit. Optionally, the first electrode layer includes a first sub-electrode corresponding to the first sub-pixel, a second sub-electrode corresponding to the second sub-pixel, and a third sub-electrode corresponding to the third sub-pixel. The first color, the second color, and the third color are three different colors. Optionally, the first light emitting layer is substantially limited within the first sub-pixel. Optionally, the second light emitting layer is substantially limited within the second sub-pixel.

Optionally, the pixel unit further includes a fourth sub-pixel in a fourth region. Optionally, the first electrode layer further includes a fourth sub-electrode for driving the fourth sub-pixel. Optionally, the light emitting unit further includes a fourth light emitting layer in the fourth sub-pixel for emitting light of a fourth color. Optionally, the fourth light emitting layer is in a same layer as the first light emitting layer and the second light emitting layer.

As used herein, the term “sub-pixel” refers to any portion of a pixel which can be independently addressable to emit a specific color. In some embodiments, a sub-pixel may include an emissive layer and a color filter. As used herein, the term “emissive layer” refers to a layer between two electrodes from which the light is generated and emitted. The emissive layer may have a single-layer structure or a stacked-layer structure including two or more sub-layers (e.g., a stacked white OLED layer). As used herein, an emissive layer and a color filter may be considered as separate components of a sub-pixel. Therefore, the emissive layer may emit a light of a color, a color filter may convert (e.g., by filtering) the light emitted from the emissive layer into a different color. Alternatively, the light emitted from the emissive layer may be converted into a different color by a color filter including (e.g., doped with) quantum dots. Accordingly, light emitted from a sub-pixel may have a color different from that of the light emitted from an emissive layer within the sub-pixel.

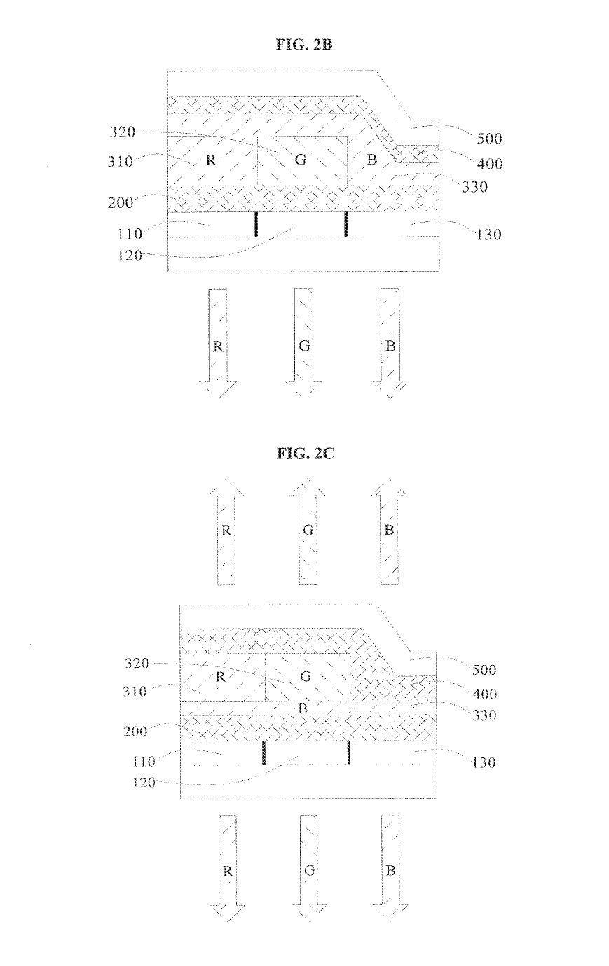

FIGS. 2A-2C, 3A-3C, and 4A-4C are diagrams illustrating several light emitting diodes in some embodiments. The light emitting diodes in the embodiments include a light emitting layer and an anode layer. The light emitting layer includes a first light emitting layer, a second light emitting layer and a third light emitting layer. Optionally, the first light emitting layer and the second light emitting layer are in a same layer. Optionally, the third light emitting layer includes a plurality of sub-layers. The third light emitting layer in the embodiments has an area larger than the sum of those of the first light emitting layer and the second light emitting layer. A portion of the third light emitting layer overlaps with the first light emitting layer and the second light emitting layer, and the remaining portion of the third light emitting layer is outside the area corresponding to the first light emitting layer and the second light emitting layer. Optionally, at least a part of the remaining portion corresponds to a third sub-pixel of the light emitting diode. Optionally, the anode layer includes a plurality of separate sub-anodes, corresponding to the first light emitting layer, the second light emitting layer, and the portion of the third light emitting layer corresponding to the third sub-pixel, respectively. For example, the anode layer may include a first sub-anode corresponding to the first light emitting layer, a second sub-anode corresponding to the second light emitting layer, and a third sub-anode corresponding to the portion of the third light emitting layer corresponding to the third sub-pixel.

Optionally, the third light emitting layer includes a single sub-layer, e.g., a single sub-layer of a light emitting material. Optionally, the third light emitting layer includes multiple sub-layers, e.g., multiple sub-layers of multiple light emitting materials. Optionally, multiple light emitting materials of the multiple sub-layers are light emitting materials of different colors, the mixture of which results in the third color. Optionally, multiple light emitting materials of the multiple sub-layers are light emitting materials of a same color (the third color).

Optionally, the third light emitting layer includes multiple sub-layers. Optionally, at least one sub-layer has a larger area than another sub-layer. Optionally, the larger sub-layer has an area larger than the sum of those of the first light emitting layer and the second light emitting layer. A portion of the larger sub-layer overlaps with the first light emitting layer and the second light emitting layer, and the remaining portion of the larger sub-layer is outside the area corresponding to the first light emitting layer and the second light emitting layer. Optionally, at least a part of the remaining portion of the larger sub-layer corresponds to a third sub-pixel of the light emitting diode.

Optionally, the third light emitting layer includes multiple sub-layers. Optionally, at least one sub-layer has a larger area than another sub-layer. Optionally, the smaller sub-layer is outside the area corresponding to the first light emitting layer and the second light emitting layer. Optionally, a portion of the larger sub-layer is outside the area corresponding to the first light emitting layer and the second light emitting layer.

In some embodiment, the first light emitting layer and the second light emitting layer are on a side of the third light emitting layer distal to the base substrate. Optionally, the third light emitting layer is on a side of the first electrode layer distal to a base substrate; the first light emitting layer and the second light emitting layer are on a side of the third light emitting layer distal to the first electrode layer, and the second electrode layer is on a side of the first light emitting layer and the second light emitting layer distal to the third light emitting layer. In some embodiment, the third light emitting layer is on a side of the first light emitting layer and the second light emitting layer distal to the base substrate. Optionally, the first light emitting layer and the second light emitting layer are on a side of the first electrode layer distal to a base substrate; the third light emitting layer is on a side of the first light emitting layer and the second light emitting layer distal to the first electrode layer, and the second electrode layer is on a side of the third light emitting layer distal to the first light emitting layer and the second light emitting layer.

In some embodiment, the first light emitting layer and the second light emitting layer are on a side of the third light emitting layer distal to the base substrate. A portion of the third light emitting layer overlaps with the first light emitting layer and the second light emitting layer, and at least a part of the remaining portion corresponds to a third sub-pixel of the light emitting diode. The first light emitting layer and the second light emitting layer correspond to the first sub-pixel and the second sub-pixel, respectively, and do not extend over to the third sub-pixel. That is, the remaining portion of the third light emitting layer is the only light emitting layer corresponds to the third sub-pixel. As discussed above, the third light emitting layer and the remaining portion thereof may, however, contain multiple sub-layers of different light emitting materials and/or different areas. A third sub-anode is on a side of the remaining portion proximal to the base substrate. When a voltage is applied between the third sub-anode and the cathode, a light of the third color emits from the remaining portion corresponding to the third sub-pixel, e.g., in a direction away from the base substrate.

In some embodiment, the third light emitting layer is on a side of the first light emitting layer and the second light emitting layer distal to the base substrate. A portion of the third light emitting layer overlaps with the first light emitting layer and the second light emitting layer, and at least a part of the remaining portion corresponds to a third sub-pixel of the light emitting diode. The first light emitting layer and the second light emitting layer correspond to the first sub-pixel and the second sub-pixel, respectively, and do not extend over to the third sub-pixel. The remaining portion of the third light emitting layer is the only light emitting layer corresponds to the third sub-pixel. As discussed above, the third light emitting layer and the remaining portion thereof may, however, contain multiple sub-layers of different light emitting materials and/or different areas. A third sub-anode is on a side of the remaining portion proximal to the base substrate. When a voltage is applied between the third sub-anode and the cathode, a light of the third color emits from the remaining portion corresponding to the third sub-pixel, e.g., in a direction away towards the base substrate.

Having a larger third light emitting layer greatly simplifies the manufacturing process of the present light emitting diode. Because the third light emitting layer is deposited throughout a region corresponding to all three sub-pixels of the light emitting diode (e.g., a region substantially corresponding to the opening of a pixel unit in the array substrate), the manufacturing of the present light emitting diode demands a much lower alignment accuracy as compared to the conventional manufacturing method, significantly simplifies the manufacturing process and lowers the manufacturing costs.

As discussed above, the third light emitting layer is a continuous emissive layer extending throughout a first region corresponding to the first sub-pixel, a second region corresponding to the second sub-pixel, and a third region corresponding to the third sub-pixel. Optionally, the third light emitting layer covers a region corresponding to an entire area of the light emitting unit of the light emitting diode. Optionally, the third light emitting layer covers a region substantially corresponding to the portion of the base substrate corresponding to the entire light emitting diode (e.g., each light emitting diode considered as an independent component of the array substrate). In a display substrate (e.g., an array substrate) having the light emitting diode, the area of the portion of the base substrate corresponding to the light emitting diode is substantially the same as the area of the opening of a pixel unit in the array substrate. Thus, in some embodiments, the third light emitting layer covers a region substantially corresponding to the opening of a pixel unit in the array substrate, and the size of the third light emitting layer is substantially the same as that of the opening of a pixel unit. Accordingly, in forming the third light emitting layer, no alignment of a mask plate with respect to an individual sub-pixel within the pixel unit is required. A considerably simplified manufacturing process and a much lower manufacturing costs can be achieved in the present light emitting diode.

In some embodiments, the light emitting diode is a top-emission type light emitting diode. Optionally, the first light emitting layer and the second light emitting layer are on a side of the third light emitting layer distal to the base substrate. In some embodiments, the light emitting diode is a bottom-emission type light emitting diode. Optionally, the third light emitting layer is on a side of the first light emitting layer and the second light emitting layer distal to the base substrate. In some embodiments, the light emitting diode is a dual-emission type light emitting mode. Optionally, the first light emitting layer and the second light emitting layer are on a side of the third light emitting layer distal to the base substrate. Alternatively, the third light emitting layer is on a side of the first light emitting layer and the second light emitting layer distal to the base substrate.

In some full-color display panels having the present light emitting diode, all light emitting layers emit light. In some such display panels, at least one light emitting layer (e.g., the third light emitting layer) emits light having an intensity different from (e.g., lower than) that of the other light emitting layers. Optionally, the light emitted from the portion of the third light emitting layer overlapping with the first light emitting layer and the second light emitting layer is blocked or absorbed by the first light emitting layer or the second light emitting layer. Optionally, the light emitted from the portion of the third light emitting layer overlapping with the first light emitting layer and the second light emitting layer has a lower intensity as compared to the light emitted from the first light emitting layer and the second tight emitting layer. Consequently, the light colors emitted from the first light emitting layer and the second light emitting layer are not affected or only negligibly affected by the light emitting from the portion of the third light emitting layer overlapping with the first light emitting layer and the second light emitting layer.

In some embodiments, the first color, the second color and the third color are three different colors selected from red, green and blue. Optionally, the first light emitting layer, the second light emitting layer, and the third light emitting layer are three different light emitting layers selected from a red light emitting layer, a green light emitting layer, and a blue light emitting layer. Optionally, the anode layer includes a first anode corresponding to the first light emitting layer, a second anode corresponding to the second light emitting layer, and a third anode corresponding to the remaining portion of the third light emitting layer (e.g., the portion outside the area corresponding to the first light emitting layer and the second light emitting layer).

FIG. 2A is a diagram illustrating a top-emission type light emitting diode in some embodiments. Referring to FIG. 2A, the light emitting diode in the embodiment includes a red light emitting layer 310, a green light emitting layer 320, and a blue light emitting layer 330. The red light emitting layer 310 and the green light emitting layer 320 are on a side of the blue light emitting layer 330 distal to the base substrate. The blue light emitting layer 330 contains a portion overlapping with the red light emitting layer 310 and the green light emitting layer 320, and a remaining portion outside of the overlapping portion (e.g., on the right side of the green light emitting layer 320 in FIG. 2A). The remaining portion corresponds to the third sub-pixel of the light emitting diode (e.g., the blue sub-pixel). As shown in FIG. 2A, a third anode 130 is on a side of the remaining portion proximal to the base substrate, a first anode 110 is on a side of the red light emitting layer 310 proximal to the base substrate, and a second anode 120 is on a side of the green light emitting layer 320 proximal to the base substrate. In forming the blue light emitting layer 330, no alignment of a mask plate with respect to an individual sub-pixel within the pixel unit is required.

FIG. 2B is a diagram illustrating a bottom-emission type light emitting diode in some embodiments. Referring to FIG. 2B, the blue light emitting layer 330 is on a side of the red light emitting layer 310 and the green light emitting layer 320 distal to the base substrate. In forming the blue light emitting layer 330, no alignment of a mask plate with respect to an individual sub-pixel within the pixel unit is required.

FIG. 2C is a diagram illustrating a dual-emission type light emitting diode in some embodiments. Referring to FIG. 2C, the red light emitting layer 310 and the green light emitting layer 320 are on a side of the blue light emitting layer 330 distal to the base substrate. In forming the blue light emitting layer 330, no alignment of a mask plate with respect to an individual sub-pixel within the pixel unit is required.

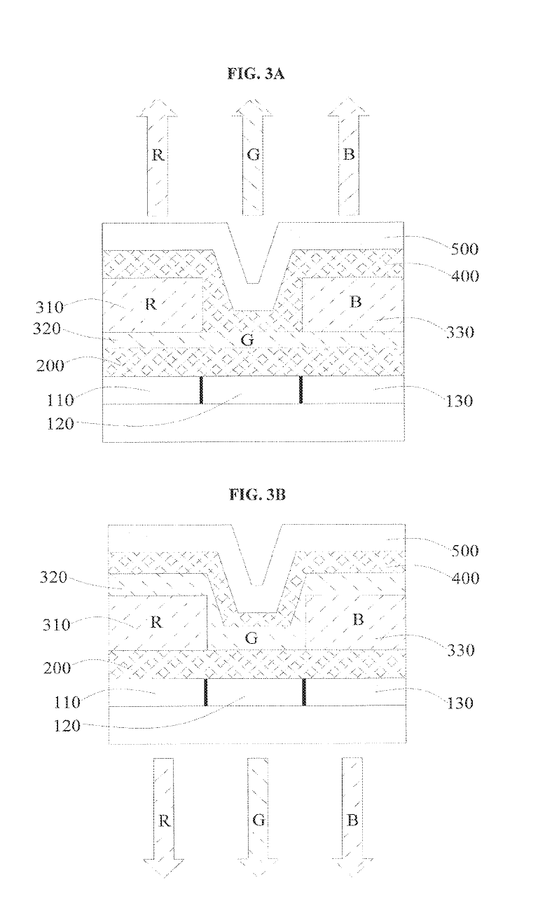

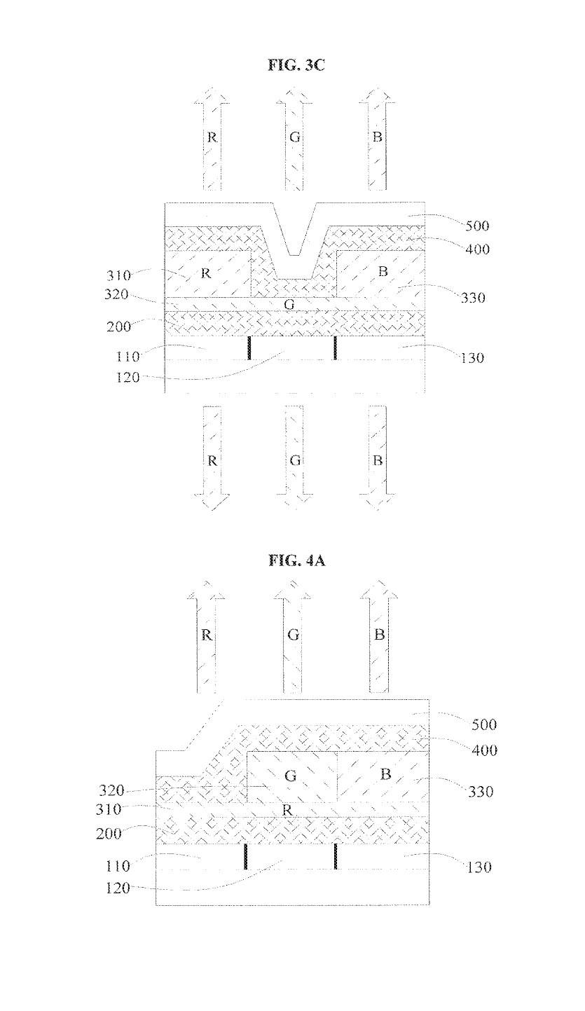

FIG. 3A is a diagram illustrating a top-emission type light emitting diode in some embodiments. Referring to FIG. 2A, the light emitting diode in the embodiment includes a red light emitting layer 310, a blue light emitting layer 330, and a green light emitting layer 320. The red light emitting layer 310 and the blue light emitting layer 330 are on a side of the green light emitting layer 320 distal to the base substrate. The green light emitting layer 320 contains a portion overlapping with the red light emitting layer 310 and the blue light emitting layer 330, and a remaining portion outside of the overlapping portion (e.g., the remaining portion is between the overlapping portion with the red light emitting layer 310 and the overlapping portion with the blue light emitting layer 330 in FIG. 3A). The remaining portion corresponds to the second sub-pixel of the light emitting diode (e.g., the green sub-pixel). As shown in FIG. 3A, a second anode 120 is on a side of the remaining portion proximal to the base substrate, a first anode 110 is on a side of the red light emitting layer 310 proximal to the base substrate, and a third anode 130 is on a side of the blue light emitting layer 330 proximal to the base substrate. In forming the green light emitting layer 320, no alignment of a mask plate with respect to an individual sub-pixel within the pixel unit is required.

FIG. 3B is a diagram illustrating a bottom-emission type light emitting diode in some embodiments. Referring to FIG. 3B, the green light emitting layer 320 is on a side of the red light emitting layer 310 and the blue light emitting layer 330 distal to the base substrate. In forming the green light emitting layer 320, no alignment of a mask plate with respect to an individual sub-pixel within the pixel unit is required.

FIG. 3C is a diagram illustrating a dual-emission type light emitting diode in some embodiments. Referring to FIG. 3C, the red light emitting layer 310 and the blue light emitting layer 330 are on a side of the green light emitting layer 320 distal to the base substrate. In forming the green light emitting layer 320, no alignment of a mask plate with respect to an individual sub-pixel within the pixel unit is required.

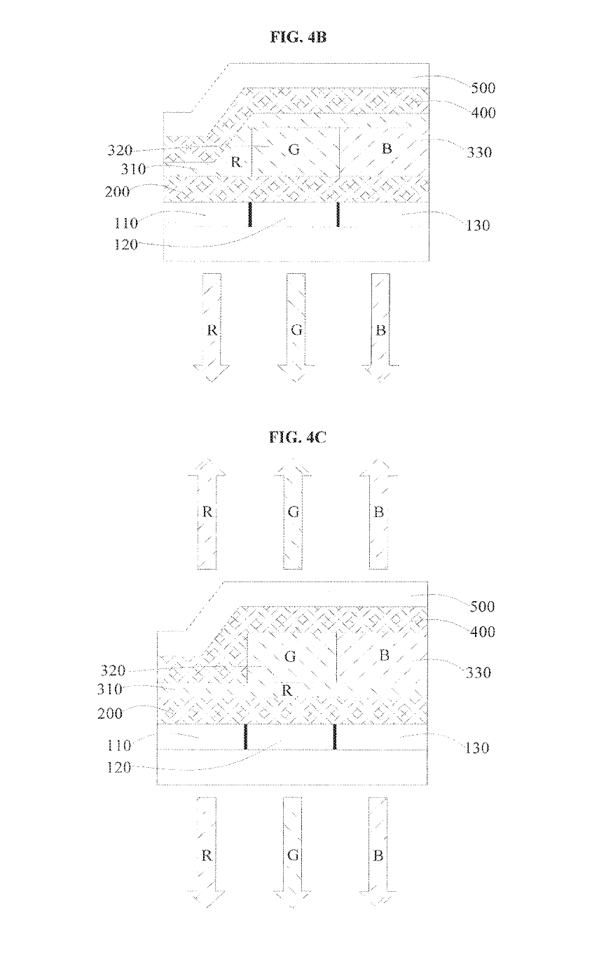

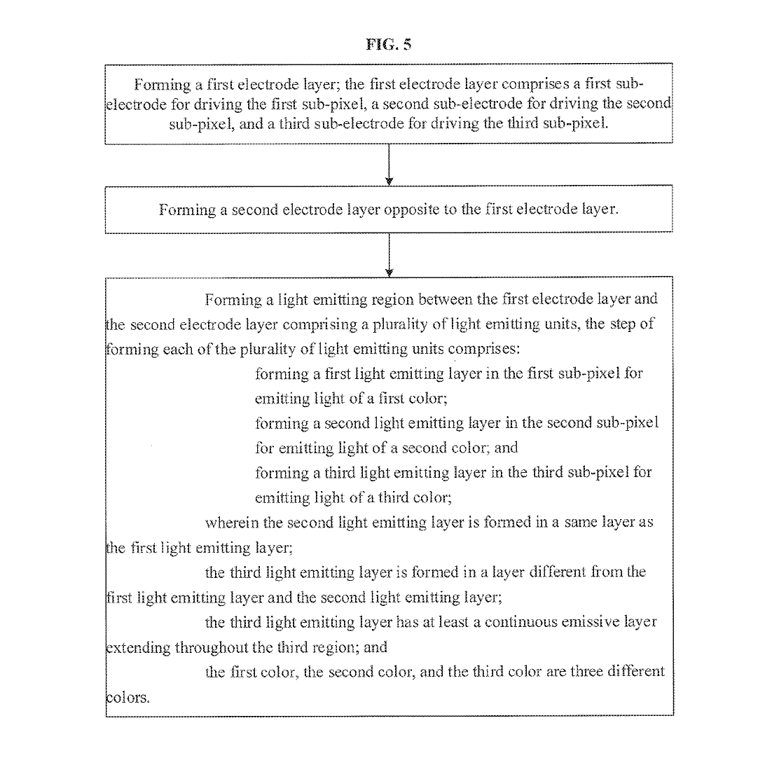

FIG. 4A is a diagram illustrating a top-emission type light emitting diode in some embodiments. Referring to FIG. 4A, the light emitting diode in the embodiment includes a red light emitting layer 310, a green light emitting layer 320, and a blue light emitting layer 330. The green light emitting layer 320 and the blue light emitting layer 330 are on a side of the red light emitting layer 310 distal to the base substrate. The red light emitting layer 310 contains a portion overlapping with the green light emitting layer 320 and the blue light emitting layer 330, and a remaining portion outside of the overlapping portion (e.g., on the left side of the green light emitting layer 320 in FIG. 4A). The remaining portion corresponds to the first sub-pixel of the light emitting diode (e.g., the red sub-pixel). As shown in FIG. 4A, a first anode 110 is on a side of the remaining portion proximal to the base substrate, a second anode 120 is on a side of the green light emitting layer 320 proximal to the base substrate, and a third anode 130 is on a side of the blue light emitting layer 330 proximal to the base substrate. In forming the red tight emitting layer 310, no alignment of a mask plate with respect to an individual sub-pixel within the pixel unit is required.

FIG. 4B is a diagram illustrating a bottom-emission type light emitting diode in some embodiments. Referring to FIG. 4B, the blue light emitting layer 330 is on a side of the red light emitting layer 310 and the green light emitting layer 320 distal to the base substrate. In forming the blue light emitting layer 330, no alignment of a mask plate with respect to an individual sub-pixel within the pixel unit is required.

FIG. 4C is a diagram illustrating a dual-emission type light emitting diode in sonic embodiments. Referring to FIG. 4C, the red light emitting layer 310 and the green light emitting layer 320 are on a side of the blue light emitting layer 330 distal to the base substrate. In forming the blue light emitting layer 330, no alignment of a mask plate with respect to an individual sub-pixel within the pixel unit is required.

In some embodiments, the present light emitting diode (e.g., those as shown in FIGS. 2A-2C, 3A-3C, and 4A-4C) further includes a hole transport layer 200 between the light emitting unit and the first electrode layer (e.g., the anode layer), and an electron transport layer 400 between the light emitting unit and the second electrode layer (e.g., the cathode layer 500).

As discussed above, the third light emitting layer is a continuous emissive layer extending throughout a first region corresponding to the first sub-pixel, a second region corresponding to the second sub-pixel, and a third region corresponding to the third sub-pixel. The first light emitting layer and the second light emitting layer overlap with a portion of the third light emitting layer, respectively. Each overlapping layer or portions thereof (e.g., the first light emitting layer, the second light emitting layer, the overlapping portions of the third light emitting layer) remains functional as a light emitting layer. For example, each overlapping layer or portions thereof can transfer charge carriers (holes and electrons), which are recombined in each overlapping layer or portions thereof, resulting in light emission.

In some embodiments, the cathode layer 500 is an integral electrode layer commonly shared by all light emitting layers and all sub-pixels. In some embodiments, the anode layer includes three separate anodes: a first anode 110, a second anode 120, and a third anode 130. In a top-emission type light emitting diode, the cathode layer 500 may be made of a transparent electrode material, and the first anode 110, the second anode 120, and the third anode 130 may be made of a reflective metal material. In a bottom-emission type light emitting diode, the cathode layer 500 may be made of a reflective metal material, and the first anode 110, the second anode 120, and the third anode 130 may be made of a transparent electrode material. In a dual-emission type light emitting diode, the cathode layer 500, the first anode 110, the second anode 120, and the third anode 130 may be made of a transflective electrode material.

In another aspect, the present disclosure provides a method of fabricating a display substrate. FIG. 5 is a flow chart illustrating a method of fabricating a display substrate in some embodiments. The display substrate in the embodiment includes a plurality of pixel units, each of which having at least a first sub-pixel in a first region, a second sub-pixel in a second region and a third sub-pixel in a third region. Referring to FIG. 5, the method in the embodiment includes forming a first electrode layer; forming a second electrode layer opposite to the first electrode layer; and forming a light emitting region between the first electrode layer and the second electrode layer having a plurality of light emitting units. The first electrode layer includes a first sub-electrode corresponding to the first sub-pixel, a second sub-electrode corresponding to the second sub-pixel, and a third sub-electrode corresponding to the third sub-pixel. The step of forming each of the plurality of light. emitting units includes forming a first light emitting layer of a first light emitting material corresponding to a first sub-pixel for emitting light of a first color; forming a second light emitting layer of a second light emitting material corresponding to a second sub-pixel for emitting light of a second color; and forming a third light emitting layer of a third light emitting material corresponding to a third sub-pixel for emitting light of a third color. The second light emitting layer is formed in a same layer as the first light emitting layer. The third light emitting layer is formed in a layer different from the first light emitting layer and the second light emitting layer. Optionally, the third light emitting layer has at least a continuous emissive layer extending throughout the third region. Optionally, the third light emitting layer is a continuous emissive layer extending throughout a first region corresponding to the first sub-pixel, a second region corresponding to the second sub-pixel, and a third region corresponding to the third sub-pixel. The first color, the second color, and the third color are three different colors.

Optionally, each pixel unit further includes a fourth sub-pixel in a fourth region. Optionally, the first electrode layer further includes a fourth sub-electrode for driving the fourth sub-pixel. Optionally, the step of forming each of the plurality of light emitting units further includes forming a fourth light emitting layer in the fourth sub-pixel for emitting light of a fourth color. Optionally, the fourth light emitting layer is in a same layer as the first light emitting layer and the second light emitting layer. Optionally, the fourth color is different from the first color, the second color, and the third color.

In some embodiments, the first light emitting layer is formed by vapor deposition using a first mask plate; the second light emitting layer is formed by vapor deposition using a second mask plate; and the third light emitting layer is formed by vapor deposition using a third mask plate. The third mask plate has an opening larger than that of the first mask plate or the second mask plate. Optionally, the third mask plate has an opening corresponding to an entire area of a light emitting unit. Optionally, the third mask plate has an opening corresponding to the portion of the base substrate corresponding to the entire light emitting diode. Optionally, the third mask plate has an opening corresponding the opening of a pixel unit in the array substrate. In each pixel unit of a display substrate manufactured by the present method, the third light emitting layer in the embodiments has an area larger than the sum of those of the first light emitting layer and the second light emitting layer. A portion of the third light emitting layer overlaps with the first light emitting layer and the second light emitting layer, and the remaining portion of the third light emitting layer is outside the area corresponding to the first light emitting layer and the second light emitting layer. Optionally, at least a part of the remaining portion corresponds to a third sub-pixel of the light emitting diode. Optionally, the anode layer includes a plurality of separate sub-anodes, corresponding to the first light emitting layer, the second light emitting layer, and the portion of the third light emitting layer corresponding to the third sub-pixel, respectively. For example, the anode layer may include a first sub-anode corresponding to the first light emitting layer, a second sub-anode corresponding to the second light emitting layer, and a third sub-anode corresponding to the portion of the third light emitting layer corresponding to the third sub-pixel.

In some embodiments, a pixel units includes a plurality of sub-pixels for emitting a plurality of different colors. Optionally, the opening of the first mask plate is substantially the same as the size of a sub-pixel (e.g., the first sub-pixel). Optionally, the opening of the second mask plate is substantially the same as the size of a sub-pixel (e.g., the second sub-pixel). During vapor deposition, a mask plate (e.g., the first mask plate or the second mask plate) is placed on the base substrate, the base substrate is then placed above a vapor deposition crucible. The material vaporized from the crucible is deposited on the base substrate through the opening of the mask plate, thereby forming a light emitting layer (e.g., the first light emitting layer or the second light emitting layer). The light emitting layer so formed has a size substantially the same as the size of a sub-pixel. For depositing different light emitting materials in multiple sub-pixels, a separate vapor deposition process utilizing a different mask plate for each sub-pixel is required.

In some embodiments, the third light emitting layer is formed by vapor deposition using a third mask. The third mask has an opening larger than that of the first mask plate or the second mask plate. A portion of the third light emitting layer overlaps with the first light emitting layer and the second light emitting layer, and the remaining portion of the third light emitting layer is outside the area corresponding to the first light emitting layer and the second light emitting layer. Optionally, at least a part of the remaining portion corresponds to the third sub-pixel of the light emitting diode, the first light emitting layer corresponds to the first sub-pixel, and the second light emitting layer corresponds to the second sub-pixel.

In forming the third light emitting layer, no alignment of a mask plate with respect to an individual sub-pixel within the pixel unit is required. A considerably simplified manufacturing process and a much lower manufacturing costs can be achieved in the present light emitting diode.

Optionally, the third mask plate has an opening substantially corresponding the opening of a pixel unit in the array substrate, and the size of the opening is substantially the same as that of the pixel unit.

In some embodiments, the display substrate manufactured by the present method is a top-emission type display substrate. Optionally, the third light emitting layer is formed prior to forming the first light emitting layer and the second light emitting layer. Optionally, the third light emitting layer is formed on a side of the first electrode layer distal to a base substrate; the first light emitting layer and the second light emitting layer are formed on a side of the third light emitting layer distal to the first electrode layer, and the second electrode layer is formed on a side of the first light emitting layer and the second light emitting layer distal to the third light emitting layer.

In some embodiments, the display substrate manufactured by the present method is a bottom-emission type display substrate. Optionally, the first light emitting layer and the second light emitting layer are formed prior to forming the third light emitting layer. Optionally, the first light emitting layer and the second light emitting layer are formed on a side of the first electrode layer distal to a base substrate; the third light emitting layer is formed on a side of the first light emitting layer and the second light emitting layer distal to the first electrode layer, and the second electrode layer is formed on a side of the third light emitting layer distal to the first light emitting layer and the second light emitting layer.

In some embodiments, the display substrate manufactured by the present method is a dual-emission type display substrate. Optionally, the third light emitting layer is formed prior to forming the first light emitting layer and the second light emitting layer. Optionally, the first light emitting layer and the second light emitting layer are formed prior to forming the third light emitting layer.

In some embodiments, the first color, the second color and the third color are three different colors selected from red, green and blue. Optionally, the first light emitting layer, the second light emitting layer, and the third light emitting layer are three different light emitting layers selected from a red light emitting layer, a green light emitting layer, and a blue light emitting layer. Optionally, the first mask plate (or the second mask plate) has an opening having a size which is about one third of that of the pixel unit. Optionally, the anode layer includes a first anode corresponding to the first light emitting layer, a second anode corresponding to the second light emitting layer, and a third anode corresponding to the remaining portion of the third light emitting layer (e.g., the portion outside the area. corresponding to the first light emitting layer and the second light emitting layer).

In some embodiments, the method further includes forming a hole function layer (e.g., a hole transport layer and/or a hole injection layer) between the light emitting region and the first electrode layer, and forming an electron function layer (e.g., an electron transport layer and/or an electron injection layer) between the light emitting region and the second electrode layer. Optionally, the first electrode layer is an anode layer, Optionally, the method includes, subsequent to forming the anode layer and prior to forming the light emitting layer, forming a hole function layer (e.g., a hole transport layer and/or a hole injection layer). Optionally, the method includes, subsequent to forming the light emitting layer, forming the electron function layer (e.g., an electron transport layer and/or an electron injection layer) and forming a cathode layer.

In another aspect, the present disclosure provides a display substrate having a plurality of pixels, each pixel comprising the light emitting diode described herein or manufactured by a method described herein.

In another aspect, the present disclosure provides a display apparatus having a display substrate described herein. Examples of display apparatus include, but are not limited to, an electronic paper, a mobile phone, a tablet computer, a television, a notebook computer, a digital album, a GPS, etc.

Having a larger third light emitting layer greatly simplifies the manufacturing process of the present display substrate and the present display apparatus. Because the third light emitting layer is deposited throughout a region corresponding to all three sub-pixels of the light emitting diode (e.g., a region substantially corresponding to the opening of a pixel unit in the array substrate), the manufacturing of the present light emitting diode demands a much lower alignment accuracy as compared to the conventional manufacturing method, significantly simplifies the manufacturing process and lowers the manufacturing costs.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “'second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A light emitting diode, comprising:
a pixel unit comprising at least a first sub-pixel in a first region, a second sub-pixel in a second region and a third sub-pixel in a third region;
a first electrode layer comprising a first sub-electrode for driving the first sub-pixel, a second sub-electrode for driving the second sub-pixel, and a third sub-electrode for driving the third sub-pixel;
a second electrode layer opposite to the first electrode layer; and
a light emitting unit between the first electrode layer and the second electrode layer comprising:
a first light emitting layer in the first sub-pixel for emitting light of a first color;
a second light emitting layer in the second sub-pixel for emitting light of a second color; and
a third light emitting layer in the third sub-pixel for emitting light of a third color;
wherein the second light emitting layer is in a same layer as the first light emitting layer;
the third light emitting layer is in a layer different from the first light emitting layer and the second light emitting layer;
the third light emitting layer has at least a continuous emissive layer extending throughout the third region;
the first color, the second color, and the third color are three different colors.

2. The light emitting diode of claim 1, wherein the third light emitting layer is a continuous emissive layer extending throughout the first region, the second region, and the third region.

3. The light emitting diode of claim 1, wherein the pixel unit further comprises a fourth sub-pixel in a fourth region;
the first electrode layer further comprises a fourth sub-electrode for driving the fourth sub-pixel;
the light emitting unit further comprises a fourth light emitting layer in the fourth sub-pixel for emitting light of a fourth color;
the fourth light emitting layer is in a same layer as the first light emitting layer and the second light emitting layer; and
the fourth color is different from the first color, the second color, and the third color.

4. The light emitting diode of claim 1, wherein the third light emitting layer covers a region substantially equal to an entire area of the light emitting unit.

5. (canceled)

6. The light emitting diode of claim 1, wherein the third light emitting layer comprises two or more sub-layers.

7. The light emitting diode of claim 1, wherein the third light emitting layer is on a side of the first electrode layer distal to a base substrate; the first light emitting layer and the second light emitting layer are on a side of the third light emitting layer distal to the first electrode layer, and the second electrode layer is on a side of the first light emitting layer and the second light emitting layer distal to the third light emitting layer.

8. (canceled)

9. The light emitting diode of claim 1, wherein the first color, the second color and the third color are three different colors selected from red, green and blue.

10. (canceled)

11. The light emitting diode of claim 1, wherein the first electrode layer is an anode layer, and the second electrode layer is a cathode layer.

12. A display substrate comprising a plurality of the light emitting diode of claim 1.

13. A method of fabricating a display substrate comprising a plurality of pixel units, each of which comprising at least a first sub-pixel in a first region, a second sub-pixel in a second region and a third sub-pixel in a third region; the method comprising:
forming a first electrode layer; the first electrode layer comprises a first sub-electrode for driving the first sub-pixel, a second sub-electrode for driving the second sub-pixel, and a third sub-electrode for driving the third sub-pixel;
forming a second electrode layer opposite to the first electrode layer; and
forming a light emitting region between the first electrode layer and the second electrode layer comprising a plurality of light emitting units, the step of forming each of the plurality of light emitting units comprises:
forming a first light emitting layer in the first sub-pixel for emitting light of a first color;
forming a second light emitting layer in the second sub-pixel for emitting light of a second color; and
forming a third light emitting layer in the third sub-pixel for emitting light of a third color;
wherein the second light emitting layer is formed in a same layer as the first light emitting layer;
the third light emitting layer is formed in a layer different from the first light emitting layer and the second light emitting layer;
the third light emitting layer has at least a continuous emissive layer extending throughout the third region; and
the first color, the second color, and the third color are three different colors.

14. The method of claim 13, wherein the third light emitting layer is a continuous emissive layer extending throughout the first region, the second region, and the third region.

15. The method of claim 13, wherein each pixel unit further comprises a fourth sub-pixel in a fourth region; the first electrode layer further comprises a fourth sub-electrode for driving the fourth sub-pixel;
the step of forming each of the plurality of light emitting units further comprises forming a fourth light emitting layer in the fourth sub-pixel for emitting light of a fourth color;
the fourth light emitting layer is in a same layer as the first light emitting layer and the second light emitting layer; and
the fourth color is different from the first color, the second color, and the third color.

16. The method of claim 13, wherein the first light emitting layer is formed by vapor deposition using a first mask plate; the second light emitting layer is formed by vapor deposition using a second mask plate; and the third light emitting layer is formed by vapor deposition using a third mask plate; the third mask plate having an opening larger than a sum of those of the first mask plate and the second mask plate.

17. The method of claim 16, wherein the third mask plate has an opening substantially corresponding to an entire area of a light emitting unit.

18. The method of claim 16, wherein the first mask plate and the second mask plate is a single mask plate.

19. (canceled)

20. The method of claim 13, wherein the third light emitting layer comprises two or more sub-layers.

21. The method of claim 13, wherein the third light emitting layer is formed on a side of the first electrode layer distal to a base substrate; the first light emitting layer and the second light emitting layer are formed on a side of the third light emitting layer distal to the first electrode layer, and the second electrode layer is formed on a side of the first light emitting layer and the second light emitting layer distal to the third light emitting layer.

22. (canceled)

23. The method of claim 13, wherein the first color, the second color and the third color are three different colors selected from red, green and blue.

24. (canceled)

25. The method of claim 13, wherein the first electrode layer is an anode layer, and the second electrode layer is a cathode layer.

26. A display apparatus comprising the display substrate of claim 12.
